(19) United States
(12) Patent Application Publication
(10) Pub. No.: US 2026/0058098 A1
(43) Pub. Date: Feb. 26, 2026

(54) MATCHING DEVICE AND PLASMA PROCESSING APPARATUS

(71) Applicant: Tokyo Electron Limited, Tokyo (JP)

(72) Inventor: Masaki HIRAYAMA, Tokyo (JP)

(21) Appl. No.: 19/301,131

(22) Filed: Aug. 15, 2025

(30) Foreign Application Priority Data
Aug. 21, 2024 (JP) 2024-139628

(51) Int. Cl. H01J 37/32; H01P 7/06

(52) U.S. Cl. CPC H01J 37/32183; H01P 7/06

(57) ABSTRACT

A matching device includes: a plurality of reactance elements connected to a radio-frequency supply line supplying radio-frequency power for plasma generation; and a plurality of relays each including a relay switch having a first contact connected to a conductor pattern of a corresponding reactance element among the plurality of reactance elements and a second contact connected to a ground pattern, and a relay coil. Each of the plurality of relays is arranged in a direction of an electric field between the conductor pattern of the corresponding reactance element among the plurality of reactance elements and the ground pattern, and the plurality of relays is rotationally symmetrically arranged with respect to a central axis of the radio-frequency supply line or is symmetrically arranged with respect to a reference plane including the central axis.

### CROSS-REFERENCE TO RELATED APPLICATION

This application is based upon and claims the benefit of priority from Japanese Patent Application No. 2024-139628, filed on Aug. 21, 2024, the entire contents of which are incorporated herein by reference.

### TECHNICAL FIELD

An exemplary embodiment of the present disclosure relates to a matching device and a plasma processing apparatus.

### BACKGROUND

A plasma processing apparatus is used to perform plasma processing on a substrate. The plasma processing apparatus includes a radio-frequency power supply that generates radio-frequency power for plasma generation and a matching device. Patent Document 1 below discloses a matching device in which a plurality of series connection circuits, each including a capacitor and a switching element connected in series, is connected in parallel.

### PRIOR ART DOCUMENT

### Patent Document

Patent Document 1: Japanese patent laid-open publication No. 2022-078495

### SUMMARY

According to one embodiment of the present disclosure, there is provided a matching device including: a plurality of reactance elements connected to a radio-frequency supply line supplying radio-frequency power for plasma generation; and a plurality of relays each including a relay switch having a first contact connected to a conductor pattern of a corresponding reactance element among the plurality of reactance elements and a second contact connected to a ground pattern, and a relay coil. Each of the plurality of relays is arranged in a direction of an electric field between the conductor pattern of the corresponding reactance element among the plurality of reactance elements and the ground pattern, and the plurality of relays is rotationally symmetrically arranged with respect to a central axis of the radio-frequency supply line or is symmetrically arranged with respect to a reference plane including the central axis.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram illustrating a plasma processing apparatus according to one exemplary embodiment.

FIG. 2 is a diagram illustrating a lower portion of a resonator of the plasma processing apparatus according to one exemplary embodiment.

FIG. 3 is a cross-sectional view illustrating a matching device according to one exemplary embodiment.

FIG. 4 is a cross-sectional view taken along line IV-IV in FIG. 3.

FIG. 5 is a cross-sectional view illustrating a matching device according to another exemplary embodiment.

FIG. 6 is a cross-sectional view taken along line VI-VI in FIG. 5.

FIG. 7 is a cross-sectional view illustrating a matching device according to still another exemplary embodiment.

FIG. 8 is a cross-sectional view taken along line VIII-VIII in FIG. 7.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, various exemplary embodiments will be described in detail with reference to the accompanying drawings. In each of the drawings, the same or corresponding parts will be denoted by the same reference numerals.

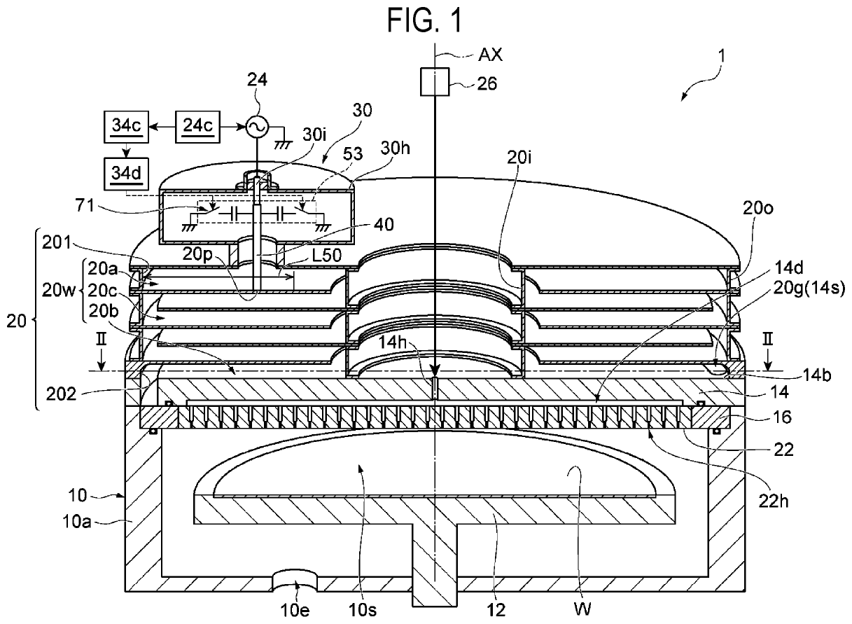

FIG. 1 is a diagram illustrating a plasma processing apparatus according to one exemplary embodiment. A plasma processing apparatus 1 illustrated in FIG. 1 includes a chamber 10, a substrate support 12, an introducer 16, a resonator 20, a radio-frequency power supply 24, and a matching device 30.

The chamber 10 provides a processing space 10s therein. In the plasma processing apparatus 1, a substrate W is processed inside the processing space 10s. The chamber 10 is made of a metal such as aluminum and is grounded. The chamber 10 has a side wall 10a and is open at an upper end thereof. The chamber 10 and the side wall 10a may have a substantially cylindrical shape. The processing space 10s is provided inside the side wall 10a. A central axis of each of the chamber 10, the side wall 10a, and the processing space 10s is an axis AX. The chamber 10 may have a corrosion-resistant film on the surface thereof. The corrosion-resistant film may be an yttrium oxide film, an yttrium oxide fluoride film, an yttrium fluoride film, or a ceramic film containing yttrium oxide, yttrium fluoride, or the like.

The bottom of the chamber 10 provides an exhaust port 10e. An exhaust device is connected to the exhaust port 10e. The exhaust device may include a vacuum pump, such as a dry pump and/or a turbomolecular pump, and an automatic pressure control valve.

The substrate support 12 is provided inside the processing space 10s. The substrate support 12 is configured to substantially horizontally support the substrate W placed on an upper surface thereof. The substrate support 12 is substantially disc-shaped. A central axis of the substrate support 12 is the axis AX.

In one embodiment, the plasma processing apparatus 1 may further include an upper electrode 14. The upper electrode 14 is provided above the substrate support 12 via the processing space 10s. The upper electrode 14 is made of a conductor such as a metal (e.g., aluminum) and is substantially disc-shaped. A central axis of the upper electrode 14 is the axis AX. The upper electrode 14 constitutes an excitation electrode together with a shower plate 22 described later.

The introducer 16 is provided to emit electromagnetic waves therefrom into a plasma generation region. In the plasma processing apparatus 1, the plasma generation region is a space provided within the processing space 10s and directly below the excitation electrode, i.e., directly below the shower plate 22. In the plasma processing apparatus 1, the electromagnetic waves emitted from the introducer 16 into the plasma generation region excite gas in the plasma generation region to generate plasma. The electromagnetic waves emitted from the introducer 16 into the plasma generation region may be radio-frequency waves such as VHF waves or UHF waves. The introducer 16 is made of a dielectric such as quartz, aluminum nitride, or aluminum oxide. In one embodiment, the introducer 16 is provided at an end of the processing space 10s in a lateral direction and extends in a circumferential direction around the axis AX. The introducer 16 may have an annular shape.

The resonator 20 includes a power feeder 20p and a waveguide 20w. The power feeder 20p is an inlet for electromagnetic waves into the waveguide 20w of the resonator 20. The electromagnetic waves are generated based on radio-frequency power generated by the radio-frequency power supply 24. The radio-frequency power supply 24 may be configured to vary the frequency of the generated radio-frequency power. The radio-frequency power supply 24 and the power feeder 20p are electrically connected via a radio-frequency supply line 40. The electromagnetic waves are input to the power feeder 20p of the resonator 20 via the radio-frequency supply line 40. The resonator 20 resonates the electromagnetic waves input to the power feeder 20p within the waveguide 20w and propagates the electromagnetic waves to the introducer 16. The electromagnetic waves are introduced from the introducer 16 into the plasma generation region. In one embodiment, the resonator 20 may be provided above the chamber 10 and on the upper electrode 14.

In one embodiment, the plasma processing apparatus 1 may further include the shower plate 22. The shower plate 22 may be made of a metal such as aluminum. The introducer 16 extends to surround the shower plate 22. The introducer 16 and the shower plate 22 are arranged to close the upper opening of the chamber 10. The shower plate 22 provides a plurality of gas holes 22h. The plurality of gas holes 22h extends in a thickness direction (vertical direction) of the shower plate 22, penetrating the shower plate 22.

The shower plate 22 is provided below the upper electrode 14. The shower plate 22 extends above the plasma generation region described previously. The shower plate 22 and the upper electrode 14 define a gas diffusion space 14d therebetween. A central axis of the gas diffusion space 14d may be the axis AX. The plurality of gas holes 22h of the shower plate 22 is connected to the gas diffusion space 14d. The upper electrode 14 also provides an inlet 14h. The inlet 14h may extend on the axis AX. The inlet 14h is connected to the gas diffusion space 14d. A gas supply 26 is connected to the gas diffusion space 14d. Gas output from the gas supply 26 is supplied to the processing space 10s via the inlet 14h, the gas diffusion space 14d, and the plurality of gas holes 22h.

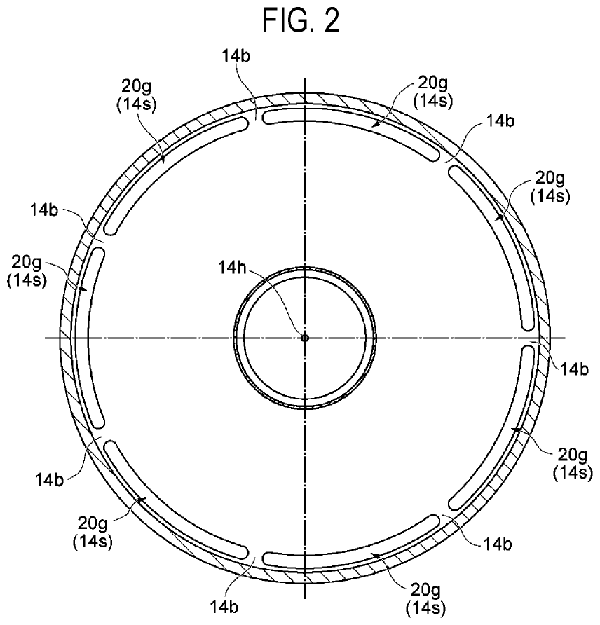

Hereinafter, reference will be made to FIG. 2 together with FIG. 1. FIG. 2 is a diagram illustrating a lower portion of the resonator of the plasma processing apparatus according to one exemplary embodiment. FIG. 2 is a cross-sectional view taken along line II-II in FIG. 1. The waveguide 20w of the resonator 20 may provide a cavity surrounded by a wall. The wall of the waveguide 20w is made of a material such as a metal. The wall of the waveguide 20w may be made of an aluminum alloy, copper, nickel, stainless steel, or the like and may be coated with a low-resistance material such as silver, gold, rhodium, or the like.

The resonator 20 includes a first stage 201 and a second stage 202. The first stage 201 and the second stage 202 constitute one end and the other end of the waveguide 20w of the resonator 20. The waveguide 20w extends between the first stage 201 and the second stage 202 and is electromagnetically coupled to the introducer 16.

In one embodiment, the wall of the resonator 20 may include an inner peripheral portion 20i and an outer peripheral portion 200. The inner peripheral portion 20i extends around the axis AX, which is a central axis thereof, and has a substantially cylindrical shape. The outer peripheral portion 200 extends coaxially with the inner peripheral portion 20i around the axis AX. The outer peripheral portion 200 may have a substantially cylindrical shape.

The waveguide 20w may have a layered structure that is alternately folded back between the inner peripheral portion 20i and the outer peripheral portion 200. The wall of the waveguide 20w may include a plurality of walls that extend in a radial direction and a circumferential direction between adjacent layers of the layered structure and between the inner peripheral portion 20i and the outer peripheral portion 200. The wall of the plurality of walls may also be an annular plate.

In addition, the waveguide 20w may include an upper portion 20a constituting the uppermost layer of the layered structure and a lower portion 20b constituting the lowermost layer of the layered structure. The layered structure may include an intermediate portion 20c between the upper portion 20a and the lower portion 20b. In this embodiment, the upper portion 20a may provide the first stage 201, i.e., an upper stage, of the waveguide 20w in the outer peripheral portion 200. In this case, the first stage 201 of the waveguide 20w extends in the circumferential direction around the axis AX. In addition, the lower portion 20b may provide the second stage 202, i.e., a lower stage, of the waveguide 20w in the outer peripheral portion 200. In this case, the second stage 202 of the waveguide 20w extends in the circumferential direction around the axis AX.

The resonator 20 provides a plurality of gaps 20g near the second stage 202 or along the second stage 202. The plurality of gaps 20g is arranged in the circumferential direction around the axis AX. The electromagnetic waves resonating in the resonator 20 are electromagnetically propagated to the introducer 16 via the plurality of gaps 20g.

In one embodiment, the upper electrode 14 provides a plurality of slots 14s as the plurality of gaps 20g and includes a plurality of beams 14b. The plurality of slots 14s is arranged above the introducer 16. The plurality of slots 14s electromagnetically couples the waveguide 20w and the introducer 16. The plurality of slots 14s penetrates the upper electrode 14 in a thickness direction (vertical direction) thereof and extends longitudinally in a circumferential direction. The plurality of slots 14s is spaced apart from each other and arranged in the circumferential direction around the axis AX. The plurality of slots 14s may be arranged at equal intervals. The plurality of beams 14b is alternately arranged with the plurality of slots 14s in the circumferential direction around the axis AX. The plurality of beams 14b connects an inner portion and an outer portion of the upper electrode 14 to each other.

In the plasma processing apparatus 1, resonance of the electromagnetic waves occurs between the first and second stages 201, 202 of the resonator 20. The electromagnetic waves resonating in the resonator 20 are supplied to the introducer 16 through the plurality of gaps 20g, i.e., the plurality of slots 14s. The electromagnetic waves supplied to the introducer 16 are emitted from the introducer 16 into the plasma generation region.

As illustrated in FIG. 1, in the plasma processing apparatus 1, the distance between the power feeder 20p and the first stage 201 in a propagation direction of the electromagnetic waves (a radial direction or the opposite direction) may be shorter than a distance L50. The distance L50 is a distance in the propagation direction between the first stage 201 and a location within the resonator 20 at which impedance viewed toward a load side therefrom during plasma excitation becomes equal to characteristic impedance of the radio-frequency supply line 40. In the plasma processing apparatus 1, since the distance between the power feeder 20p and the first stage 201 is shorter than the distance L50, a harmonic voltage at the power feeder 20p is low. Therefore, according to the plasma processing apparatus 1, it is possible to suppress harmonics returning to the radio-frequency power supply 24. As a result, the plasma processing apparatus 1 can suppress effects such as loss of radio-frequency power and abnormal oscillation in the radio-frequency power supply.

The matching device 30 is connected to the radio-frequency supply line 40 between the radio-frequency power supply 24 and the resonator 20. The matching device 30 includes an input portion 30i. The input portion 30i is a part of the radio-frequency supply line 40 and is configured, for example, as a coaxial connector. The radio-frequency power supply 24 is connected to the input portion 30i. The radio-frequency power supply 24 and the power feeder 20p are connected to each other by the radio-frequency supply line 40.

The matching device 30 includes a matching circuit. The matching circuit includes a variable reactance portion 53. The variable reactance portion 53 includes a plurality of reactance elements and a plurality of relays 71. The variable reactance portion 53 is arranged inside a grounded housing 30h (e.g., a metal housing). The variable reactance portion 53 is connected between the radio-frequency supply line 40 and a ground. That is, the plurality of reactance elements of the variable reactance portion 53 is connected to the radio-frequency supply line 40. Each of the plurality of relays 71 is connected between the ground and the plurality of reactance elements of the variable reactance portion 53.

The matching device 30 further includes a driving circuit 34d and a control circuit 34c. The driving circuit 34d is configured as a circuit for changing the impedance of the variable reactance portion 53. The control circuit 34c is configured to control the driving circuit 34d. The control circuit 34c may be configured as a programmable processor such as a central processing unit (CPU) or a micro processor unit (MPU), a programmable logic device such as a field programmable gate array (FPGA), or a dedicated circuit such as an application specific integrated circuit (ASIC).

In one embodiment, the plasma processing apparatus 1 may further include a directional coupler and a power controller 24c. The directional coupler may be provided within the radio-frequency power supply 24 or between the radio-frequency power supply 24 and the input portion 30i. The power controller 24c may be configured as a programmable processor such as a CPU or MPU, a programmable logic device such as an FPGA, or a dedicated circuit such as an ASIC.

The directional coupler outputs a signal reflecting a power level of a reflected wave of the radio-frequency power to the power controller 24c. The power controller 24c controls the radio-frequency power supply 24 or the matching device 30 to reduce the power level of the reflected wave according to the signal from the directional coupler. The power controller 24c may control the radio-frequency power supply 24 to adjust the frequency of the radio-frequency power in order to reduce the power level of the reflected wave. Alternatively or additionally, the power controller 24c may communicate with the control circuit 34c and cause the driving circuit 34d to adjust the reactance of the variable reactance portion 53 in order to reduce the power level of the reflected wave.

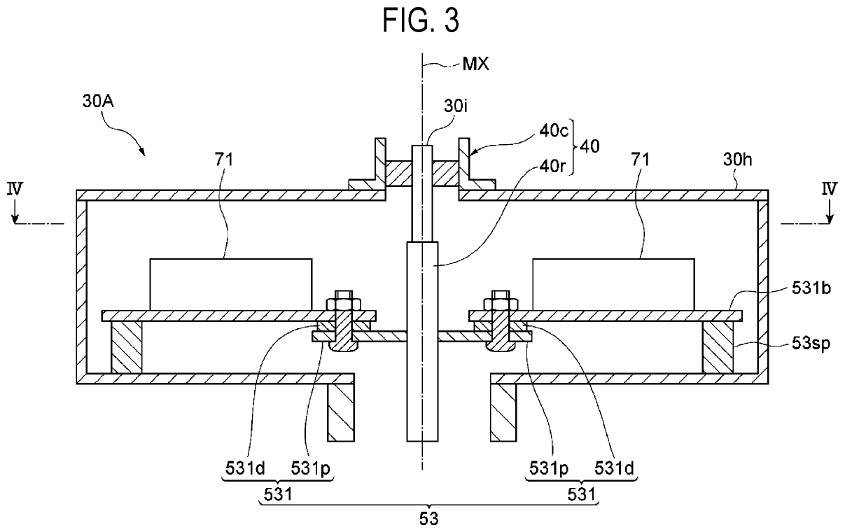

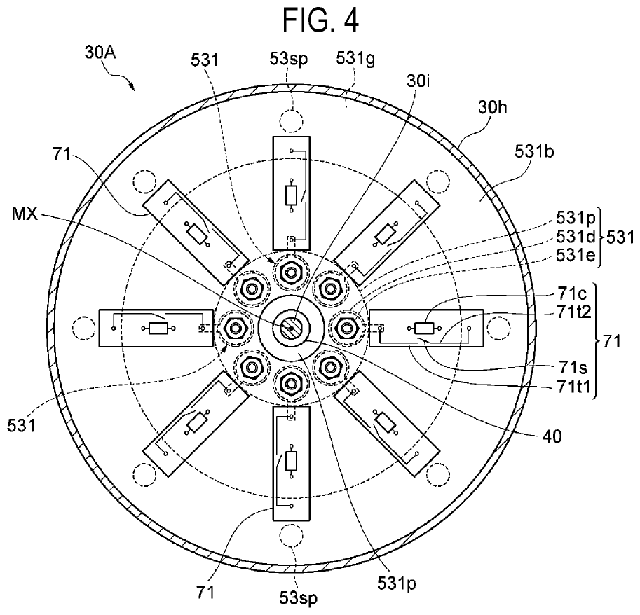

Hereinafter, reference is made to FIGS. 3 and 4 in addition to FIGS. 1 and 2. FIG. 3 is a cross-sectional view illustrating a matching device according to one exemplary embodiment. FIG. 4 is a cross-sectional view taken along line IV-IV in FIG. 3. FIG. 4 illustrates a longitudinal cross-sectional structure of the matching device.

A matching device 30A illustrated in FIGS. 3 and 4 can be employed as the matching device 30 in the plasma processing apparatus 1. When the matching device 30A is used, the radio-frequency supply line 40 may include a metallic coupling rod 40r. The coupling rod 40r is connected between the input portion 30i (i.e., an inner conductor of a coaxial connector 40c) and the power feeder 20p and extends downward from the input portion 30i.

In the matching device 30A, the variable reactance portion 53 is arranged within the housing 30h. In the matching device 30A, the housing 30h may have a cylindrical shape. The variable reactance portion 53 of a matching circuit of the matching device 30A includes a plurality of capacitance elements 531 as the plurality of reactance elements and also includes the plurality of relays 71.

Each of the plurality of capacitor elements 531 is connected to the radio-frequency supply line 40 (e.g., the coupling rod 40r). Specifically, one of a pair of electrodes of each of the plurality of capacitor elements 531 is connected to the radio-frequency supply line 40 (e.g., the coupling rod 40r). Each of the plurality of capacitor elements 531 includes a conductor pattern 531e (a capacitor electrode pattern). The conductor pattern 531e serves as the other electrode of the pair of electrodes of each of the plurality of capacitor elements 531.

Each of the plurality of relays 71 includes a relay switch 71s and a relay coil 71c. The relay switch 71s includes a first contact 71t1 and a second contact 71t2, and depending on the state (open or closed) of the relay switch 71s, the relay switch 71s switches between disconnection and connection between the first contact 71t1 and the second contact 71t2. The first contact 71t1 of the relay switch 71s of each of the plurality of relays 71 is connected to the conductor pattern 531e of the corresponding capacitor element 531 among the plurality of capacitor elements 531. In addition, the second contact 71t2 of the relay switch 71s of each of the plurality of relays 71 is connected to a ground pattern 531g.

In the matching device 30A, the driving circuit 34d is configured to apply a direct current voltage signal to the relay coil 71c of each of the plurality of relays 71 in order to set the state (open or closed state) of the relay switch 71s of each of the plurality of relays 71. The control circuit 34c is capable of communicating with the power controller 24c via a communication circuit. The control circuit 34c is notified of a setting value of capacitance of the variable reactance portion 53 for reducing the power level of the reflected wave by the power controller 24c via the communication circuit. In order to set the capacitance of the variable reactance portion 53 to the notified setting value, the control circuit 34c controls the driving circuit 34d so as to set the state of the relay switch 71s of each of the plurality of relays 71.

In the matching device 30A, the conductor pattern 531e of each of the plurality of capacitor elements 531, i.e., the plurality of conductor patterns 531e, is arranged rotationally symmetrically with respect to a central axis MX of the radio-frequency supply line 40 (e.g., the coupling rod 40r). Each of the plurality of relays 71 is arranged in the direction of an electric field between the conductor pattern 531e of the corresponding capacitor element among the plurality of capacitor elements 531 and the ground pattern 531g. Furthermore, the plurality of relays 71 is arranged rotationally symmetrically with respect to the central axis MX of the radio-frequency supply line 40. For example, the plurality of relays 71 is arranged such that current paths of radio-frequency current in the relays 71 including the relay switches 71s are rotationally symmetrically positioned with respect to the central axis MX.

Inside the housing 30h of the matching device 30A, electromagnetic waves in a TEM mode propagate in a direction along which the central axis MX extends, and a radio-frequency electric field in a radial direction with respect to the central axis MX is uniformly formed in a circumferential direction with respect to the axis AX. Therefore, the radio-frequency electric field that extends in the radial direction and has substantially the same intensity is applied to each of the plurality of relays 71. Accordingly, the difference in influence of stray impedance of each of the plurality of relays 71 is reduced. According to such a matching device 30A, it is possible to regularly change total impedance by driving the plurality of relays 71.

In one embodiment, as shown in FIG. 4, the plurality of relays 71 may be arranged at equal intervals in the circumferential direction with respect to the central axis MX. In addition, each of the plurality of capacitor elements 531 and the corresponding relay among the plurality of relays 71 may be aligned in the radial direction with respect to the central axis MX between the radio-frequency supply line 40 (e.g., the coupling rod 40r) and the ground pattern 531g.

In one embodiment, the matching device 30A may further include a printed circuit board 531b. The printed circuit board 531b is provided inside the housing 30h and extends in a horizontal direction. The printed circuit board 531b has a substantially circular shape and is open at the center thereof. The radio-frequency supply line 40 extends through the opening of the printed circuit board 531b.

The printed circuit board 531b may have the plurality of relays 71 mounted on an upper surface thereof. The printed circuit board 531b may provide the plurality of conductor patterns 531e and the ground pattern 531g on a lower surface thereof. The plurality of conductor patterns 531e and the ground pattern 531g are made of a metal such as copper. The plurality of conductor patterns 531e have a substantially circular shape and is arranged in the circumferential direction around the central axis MX. The plurality of conductor patterns 531e may be arranged at equal intervals. The ground pattern 531g extends in a radially outward position with respect to the plurality of conductor patterns 531e. The ground pattern 531g may have an annular shape and may extend around the central axis MX. The ground pattern 531g is connected to the bottom of the housing 30h, i.e., to a ground, via a plurality of metal support columns 53sp.

The matching device 30A further includes a capacitor plate 531p made of a metal such as copper. The capacitor plate 531p extends below the printed circuit board 531b so as to face the plurality of conductor patterns 531e. The capacitor plate 531p may have a substantially annular shape. An inner edge of the capacitor plate 531p is connected to the radio-frequency supply line 40 (e.g., the coupling rod 40r). The capacitor plate 531p constitutes a common electrode used as one of a pair of electrodes of each of the plurality of capacitor elements 531.

The matching device 30A also includes a plurality of dielectric members 531d. The plurality of dielectric members 531d is made of, for example, polytetrafluoroethylene. The plurality of dielectric members 531d may have a ring shape. Each of the plurality of dielectric members 531d is held between the corresponding conductor pattern among the plurality of conductor patterns 531e and the capacitor plate 531p. Each of the plurality of capacitor elements 531 is composed of one conductor pattern among the plurality of conductor patterns 531e, the capacitor plate 531p, and a dielectric member arranged between the conductor pattern and the capacitor plate 531p among the plurality of dielectric members 531d.

The plurality of conductor patterns 531e may have the same area. In this case, the plurality of capacitor elements 531 have the same capacitance (electrostatic capacity). In addition, an edge of each of the plurality of conductor patterns 531e may have a slightly smaller size than the size of the plurality of dielectric members 531d so that the edge of each of the plurality of conductor patterns 531e is located inward of an edge of the corresponding dielectric member among the plurality of dielectric members 531d. This configuration can suppress creepage discharge.

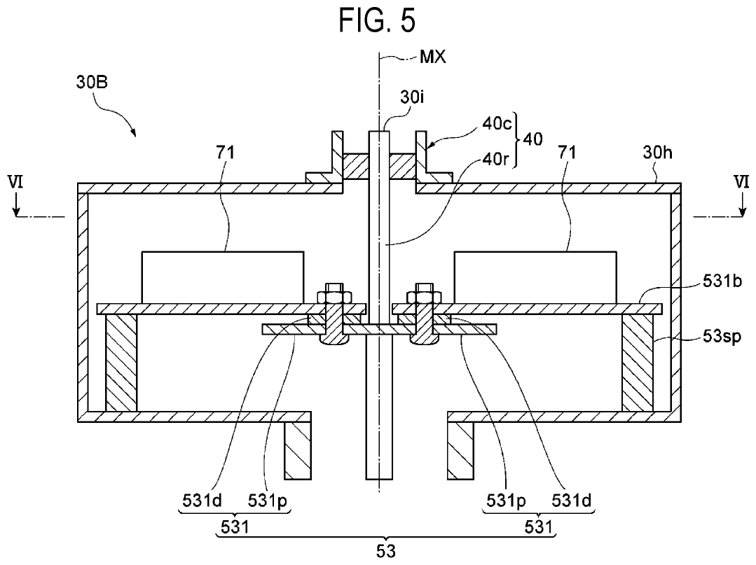

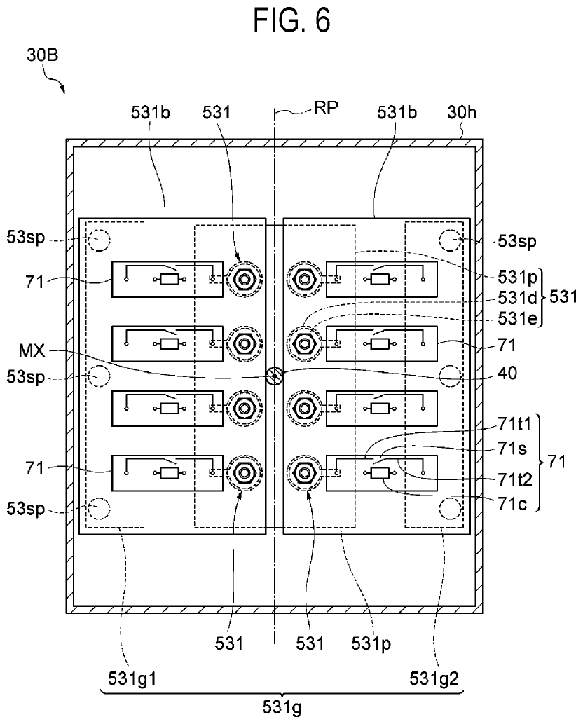

Next, a matching device according to another exemplary embodiment will be described with reference to FIGS. 5 and 6. FIG. 5 is a cross-sectional view illustrating a matching device according to another exemplary embodiment, and FIG. 6 is a cross-sectional view taken along line VI-VI of FIG. 5. A matching device 30B illustrated in FIGS. 5 and 6 can be employed as the matching device 30 in the plasma processing apparatus 1. The matching device 30B will now be described from the viewpoints of differences from the matching device 30A.

In the matching device 30B, the plurality of capacitor elements 531 is symmetrically arranged with respect to a reference plane RP including the central axis MX. Similarly to the matching device 30A, in the matching device 30B, each of the plurality of relays 71 is arranged in the direction of an electric field between the ground pattern 531g and the conductor pattern 531e of the corresponding capacitor element among the plurality of capacitor elements 531.

The plurality of relays 71 is symmetrically arranged with respect to the reference plane RP. For example, the plurality of relays 71 is arranged such that current paths of radio-frequency current in the relays 71 including the relay switches 71s are symmetrically positioned with respect to the reference plane RP.

In the matching device 30B as well, the radio-frequency electric field that extends in the radial direction and has substantially the same intensity is applied to each of the plurality of relays 71. Therefore, the difference in influence of stray impedance of each of the plurality of relays 71 is reduced. According to such a matching device 30B, it is possible to regularly change total impedance by driving the plurality of relays 71.

In the matching device 30B, the housing 30h may have a substantially rectangular parallelepiped shape. In the matching device 30B, each of the printed circuit board 531b and the capacitor plate 531p may have a substantially rectangular shape.

In the matching device 30B as well, the printed circuit board 531b may have the plurality of relays 71 mounted on the upper surface thereof. The printed circuit board 531b may provide the plurality of conductor patterns 531e and the ground pattern 531g on the lower surface thereof. In the matching device 30B as well, each of the plurality of capacitor elements 531 is composed of one conductor pattern among the plurality of conductor patterns 531e, the capacitor plate 531p, and a dielectric member arranged between the conductor pattern and the capacitor plate 531p among the plurality of dielectric members 531d.

In the matching device 30B, the plurality of capacitor elements 531 is arranged in a first direction that is parallel to the reference plane RP and orthogonal to the central axis MX. The plurality of capacitor elements 531 may be arranged at equal intervals. The plurality of relays 71 is also arranged in the first direction. The plurality of relays 71 may also be arranged at equal intervals.

In the matching device 30B, the ground pattern 531g may include a first ground pattern 531g1 and a second ground pattern 531g2. The first ground pattern 531g1 is arranged on one side with respect to the reference plane RP, and the second ground pattern 531g2 is disposed on the other side with respect to the reference plane RP. Each of the first and second ground patterns 531g1 and 531g2 may have a substantially rectangular shape and may extend in the first direction.

In the matching device 30B, each of the plurality of capacitor elements 531 and the corresponding relay among the plurality of relays 71 are aligned in a position that is one side or the other side with respect to the reference plane RP between the reference plane RP and the first ground pattern 531g1 or the second ground pattern 531g2 in a second direction that is orthogonal to the reference plane RP. That is, each of a plurality of first capacitor elements arranged on one side with respect to the reference plane RP among the plurality of capacitor elements 531 and the corresponding relay 71 are aligned in the second direction between the reference plane RP and the first ground pattern 531g1. In addition, each of a plurality of second capacitor elements arranged on the other side with respect to the reference plane RP among the plurality of capacitor elements 531 and the corresponding relay 71 are aligned in the second direction between the reference plane RP and the second ground pattern 531g2.

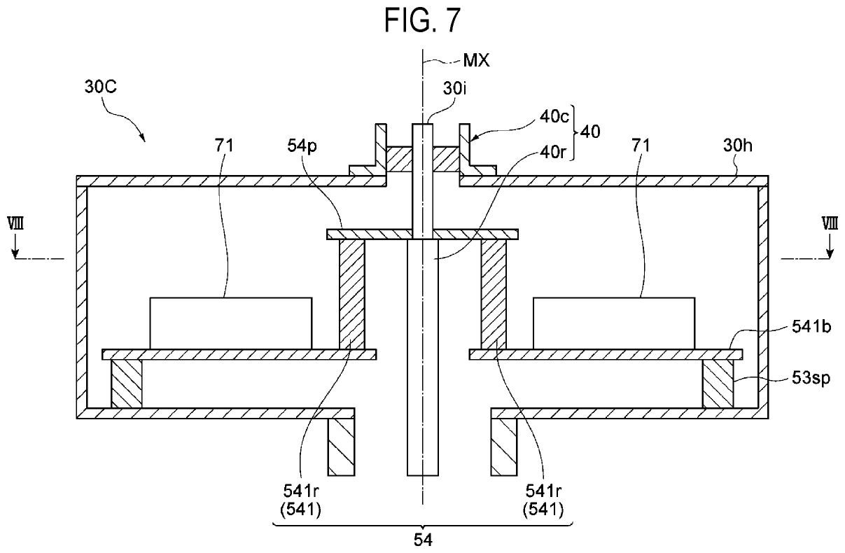

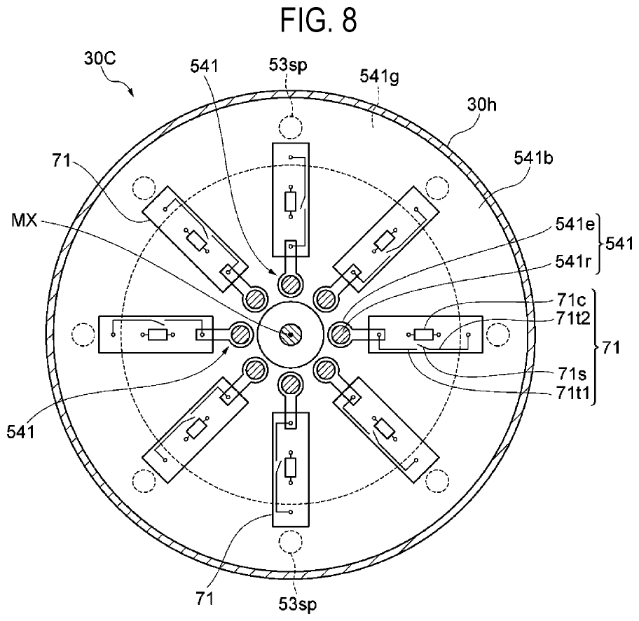

Hereinbelow, a matching device according to still another exemplary embodiment will be described with reference to FIGS. 7 and 8. FIG. 7 is a cross-sectional view illustrating a matching device according to still another exemplary embodiment. FIG. 8 is a cross-sectional view taken along line VIII-VIII in FIG. 7. A matching device 30C illustrated in FIGS. 7 and 8 can be employed as the matching device 30 in the plasma processing apparatus 1. In the plasma processing apparatus 1 including the matching device 30C, the distance between the power feeder 20p and the first stage 201 in the propagation direction of the electromagnetic waves may be longer than the distance L50. Hereinafter, the matching device 30C will be described from the viewpoint of differences from the matching device 30A.

A matching circuit of the matching device 30C includes a variable reactance portion 54 instead of the variable reactance portion 53. The variable reactance portion 54 is arranged within the housing 30h. In the matching device 30C, the housing 30h may have a cylindrical shape. The variable reactance portion 54 includes a plurality of inductor elements 541 as a plurality of reactance elements and also includes the plurality of relays 71.

Each of the plurality of inductor elements 541 may have the same inductance. Each of the plurality of inductor elements 541 is connected to the radio-frequency supply line 40 (e.g., the coupling rod 40r). Each of the plurality of inductor elements 541 may be connected to the coupling rod 40r via a power distribution board 54p. The power distribution board 54p may be a substantially annular plate, and an inner edge of the power distribution board 54p may be connected to the coupling rod 40r.

Each of the plurality of inductor elements 541 may include a conductor pattern 541e. The conductor pattern 541e may have a substantially circular shape. The conductor pattern 541e of each of the plurality of inductor elements 541, i.e., the plurality of conductor patterns 541e, may be arranged below the power distribution board 54p. Each of the plurality of inductor elements 541 may include a rod 541r. The rod 541r extends in the vertical direction between the power distribution board 54p and the corresponding conductor pattern among the plurality of conductor patterns 541e.

The plurality of conductor patterns 541e is rotationally symmetrically arranged with respect to the central axis MX of the radio-frequency supply line 40 (e.g., the coupling rod 40r). In the matching device 30C, each of the plurality of relays 71 is arranged in the direction of an electric field between the conductor pattern 541e of the corresponding inductor element 541 among the plurality of inductor elements 541 and the ground pattern 531g. Furthermore, in the matching device 30C, the plurality of relays 71 is rotationally symmetrically arranged with respect to the central axis MX of the radio-frequency supply line 40. For example, the plurality of relays 71 is arranged such that current paths of radio-frequency current in the relays 71 including the relay switches 71s are rotationally symmetrically arranged with respect to the central axis MX.

Inside the housing 30h of the matching device 30C as well, the electromagnetic waves in the TEM mode propagate in a direction along which the central axis MX extends, and a radio-frequency electric field in the radial direction with respect to the central axis MX is uniformly formed in the circumferential direction with respect to the axis AX. Therefore, the radio-frequency electric field that extends in the radial direction and has substantially the same intensity is applied to each of the plurality of relays 71. Accordingly, the difference in influence of stray impedance of each of the plurality of relays 71 is reduced. According to such a matching device 30C, it is possible to regularly change total impedance by driving the plurality of relays 71.

In one embodiment, as illustrated in FIG. 8, in the matching device 30C, the plurality of relays 71 may also be arranged at equal intervals in the circumferential direction with respect to the central axis MX. Further, each of the plurality of inductor elements 541 and the corresponding relay among the plurality of relays 71 may be aligned in the radial direction with respect to the central axis MX between the radio-frequency supply line 40 (e.g., the coupling rod 40r) and a ground pattern 541g.

In one embodiment, the matching device 30C may further include a printed circuit board 541b. The printed circuit board 541b is provided inside the housing 30h and extends in a horizontal direction. The printed circuit board 541b has a substantially circular shape and is open at the center thereof. The radio-frequency supply line 40 extends via the opening of the printed circuit board 541b.

The printed circuit board 541b may have the plurality of relays 71 mounted on an upper surface thereof. The printed circuit board 541b may provide the plurality of conductor patterns 541e on an upper surface thereof and the ground pattern 541g on a lower surface thereof. The plurality of conductor patterns 541e and the ground pattern 541g are made of a metal such as copper. The plurality of conductor patterns 541e have a substantially circular shape and is arranged in the circumferential direction around the central axis MX. The plurality of conductor patterns 541e may be arranged at equal intervals. The ground pattern 541g extends in a radially outward position with respect to the plurality of conductor patterns 541e. The ground pattern 541g may have an annular shape and extend around the central axis MX. The ground pattern 541g is connected to the bottom of the housing 30h, i.e., to a ground, via the plurality of metal support columns 53sp.

While various exemplary embodiments have been described above, the present disclosure is not limited to the above-described exemplary embodiments, and various additions, omissions, substitutions, and modifications may be made. In addition, elements in different embodiments can be combined to form other embodiments.

For example, in still another exemplary embodiment, the plurality of inductor elements 541 and the plurality of relays 71 may be symmetrically arranged with respect to the reference plane RP, similarly to the plurality of capacitor elements 531 and the plurality of relays 71 in the matching device 30B.

Here, various exemplary embodiments included in the present disclosure are described in [E1] to [E11] below.
[E1] A matching device, comprising:
a plurality of reactance elements connected to a radio-frequency supply line supplying radio-frequency power for plasma generation; and
a plurality of relays each including a relay switch having a first contact connected to a conductor pattern of a corresponding reactance element among the plurality of reactance elements and a second contact connected to a ground pattern, and a relay coil,
wherein each of the plurality of relays is arranged in a direction of an electric field between the conductor pattern of the corresponding reactance element among the plurality of reactance elements and the ground pattern, and
wherein the plurality of relays is rotationally symmetrically arranged with respect to a central axis of the radio-frequency supply line or is symmetrically arranged with respect to a reference plane including the central axis
[E2] The matching device of [E1], wherein each of the plurality of reactance elements is a capacitor element.
[E3] The matching device of [E1], wherein each of the plurality of reactance elements is an inductor element.
[E4] The matching device of any one of [E1] to [E3], wherein the plurality of reactance elements is arranged at equal intervals in a circumferential direction with respect to the central axis,
wherein the plurality of relays is arranged at equal intervals in the circumferential direction,
wherein the ground pattern has an annular shape and extends around the central axis, and
wherein each of the plurality of reactance elements and a corresponding relay among the plurality of relays are aligned in a radial direction with respect to the central axis, between the radio-frequency supply line and the ground pattern.
[E5] The matching device of [E4], further comprising a metal housing,
wherein the metal housing has a cylindrical shape and accommodates the plurality of reactance elements and the plurality of relays therein.
[E6] The matching device of any one of [E1] to [E3], wherein the plurality of reactance elements is arranged in a first direction that is parallel to the reference plane and orthogonal to the central axis,
wherein the plurality of relays is arranged in the first direction,
wherein the ground pattern includes a first ground pattern and a second ground pattern arranged on one side and the other side with respect to the reference plane, respectively,
wherein the first ground pattern and the second ground pattern have a rectangular shape and extend in the first direction, and
wherein each of the plurality of reactance elements and a corresponding relay among the plurality of relays are aligned in a position that is the one side or the other side, between the reference plane and the first ground pattern or the second ground pattern, in a second direction that is orthogonal to the reference plane.
[E7] The matching device of [E6], further comprising a metal housing,
wherein the metal housing has a rectangular parallelepiped shape and accommodates the plurality of reactance elements and the plurality of relays therein.
[E8] The matching device of any one of [E1] to [E7], further comprising a driving circuit configured to apply a direct current voltage signal to the relay coil of each of the plurality of relay coils in order to set an open/closed state of the relay switch of each of the plurality of relays.
[E9] The matching device of any one of [E1] to [E8], further comprising a printed circuit board configured to provide the conductor pattern of each of the plurality of reactance elements and the ground pattern and having the plurality of relays mounted thereon.
[E10] A plasma processing apparatus, comprising
a chamber;
an introducer arranged to introduce electromagnetic waves into a plasma generation region inside the chamber;
a radio-frequency power supply;
the radio-frequency supply line electrically connected to the radio-frequency power supply;
a resonator including a power feeder serving as an inlet for the electromagnetic waves and connected to the radio-frequency supply line, first and second stages configured to resonate the electromagnetic waves therebetween, and a waveguide extending between the first and second stages and electromagnetically coupled to the introducer; and
the matching device of any one of [E1] to [E9], connected to the radio-frequency supply line between the radio-frequency power supply and the power feeder.
[E11] The plasma processing apparatus of [E10], wherein the resonator includes:
an inner peripheral portion extending around a central axis of the chamber and the resonator;
an outer peripheral portion extending around the central axis;
the waveguide having a layered structure of being alternately folded back between the inner peripheral portion and the outer peripheral portion;
an upper portion located at an uppermost layer of the layered structure and configured to provide the first stage at the outer peripheral portion; and
a lower portion located at a lowermost layer of the layered structure and configured to provide the second stage at the outer peripheral portion and provide a plurality of slots coupling the waveguide and the introducer to each other along the second stage.

According to the present disclosure in some embodiments, it is possible to reduce the difference in influence of stray impedance of each of the plurality of relays of the matching device of the plasma processing apparatus.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosures.

What is claimed is:

1. A matching device, comprising:
a plurality of reactance elements connected to a radio-frequency supply line for radio-frequency power for plasma generation; and
a plurality of relays each including a relay switch having a first contact connected to a conductor pattern of a corresponding reactance element among the plurality of reactance elements and a second contact connected to a ground pattern, and a relay coil,
wherein each of the plurality of relays is arranged in a direction of an electric field between the conductor pattern of the corresponding reactance element among the plurality of reactance elements and the ground pattern, and
wherein the plurality of relays is rotationally symmetrically arranged with respect to a central axis of the radio-frequency supply line or is symmetrically arranged with respect to a reference plane including the central axis.

2. The matching device of claim 1, wherein each of the plurality of reactance elements is a capacitor element.

3. The matching device of claim 2, wherein the plurality of reactance elements is arranged at equal intervals in a circumferential direction with respect to the central axis,
wherein the plurality of relays is arranged at equal intervals in the circumferential direction,
wherein the ground pattern has an annular shape and extends around the central axis, and
wherein each of the plurality of reactance elements and a corresponding relay among the plurality of relays are aligned in a radial direction with respect to the central axis, between the radio-frequency supply line and the ground pattern.

4. The matching device of claim 3, further comprising a metal housing,
wherein the metal housing has a cylindrical shape and accommodates the plurality of reactance elements and the plurality of relays therein.

5. The matching device of claim 1, wherein each of the plurality of reactance elements is an inductor element.

6. The matching device of claim 1, wherein the plurality of reactance elements is arranged in a first direction that is parallel to the reference plane and orthogonal to the central axis,
wherein the plurality of relays is arranged in the first direction,
wherein the ground pattern includes a first ground pattern and a second ground pattern arranged on one side and the other side with respect to the reference plane, respectively,
wherein the first ground pattern and the second ground pattern have a rectangular shape and extend in the first direction, and
wherein each of the plurality of reactance elements and a corresponding relay among the plurality of relays are aligned in a position that is the one side or the other side, between the reference plane and the first ground pattern or the second ground pattern, in a second direction that is orthogonal to the reference plane.

7. The matching device of claim 6, further comprising a metal housing,
wherein the metal housing has a rectangular parallelepiped shape and accommodates the plurality of reactance elements and the plurality of relays therein.

8. The matching device of claim 1, further comprising a driving circuit configured to apply a direct current voltage signal to the relay coil of each of the plurality of relay coils in order to set an open/closed state of the relay switch of each of the plurality of relays.

9. The matching device of claim 1, further comprising a printed circuit board configured to provide the conductor pattern of each of the plurality of reactance elements and the ground pattern and having the plurality of relays mounted thereon.

10. A plasma processing apparatus, comprising
a chamber;
an introducer arranged to introduce electromagnetic waves into a plasma generation region inside the chamber;
a radio-frequency power supply;
the radio-frequency supply line electrically connected to the radio-frequency power supply;
a resonator including a power feeder serving as an inlet for the electromagnetic waves and connected to the radio-frequency supply line, first and second stages configured to resonate the electromagnetic waves therebetween, and a waveguide extending between the first and second stages and electromagnetically coupled to the introducer; and
the matching device according to claim 1, connected to the radio-frequency supply line between the radio-frequency power supply and the power feeder.

11. The plasma processing apparatus of claim 10, wherein the resonator includes:
an inner peripheral portion extending around a central axis of the chamber and the resonator;
an outer peripheral portion extending around the central axis;
the waveguide having a layered structure of being alternately folded back between the inner peripheral portion and the outer peripheral portion;
an upper portion located at an uppermost layer of the layered structure and configured to provide the first stage at the outer peripheral portion; and
a lower portion located at a lowermost layer of the layered structure and configured to provide the second stage at the outer peripheral portion and provide a plurality of slots coupling the waveguide and the introducer to each other along the second stage.

12. The matching device of claim 1, wherein the plurality of reactance elements is arranged at equal intervals in a circumferential direction with respect to the central axis,
wherein the plurality of relays is arranged at equal intervals in the circumferential direction,
wherein the ground pattern has an annular shape and extends around the central axis, and
wherein each of the plurality of reactance elements and a corresponding relay among the plurality of relays are aligned in a radial direction with respect to the central axis, between the radio-frequency supply line and the ground pattern.
